(19) United States
(12) Patent Application Publication
(10) Pub. No.: US 2005/0264995 A1
(43) Pub. Date: Dec. 1, 2005

(54) Downdraft cooling system for in-line devices

(75) Inventor: George E. Hanson, Andover, KS (US)

Correspondence Address: LSI LOGIC CORPORATION, 1621 BARBER LANE, MS: D-106, MILPITAS, CA, 95035, US

(73) Assignee: LSI Logic Corporation, Milpitas, CA (US)

(21) Appl. No.: 10/857,216

(22) Filed: May 28, 2004

(51) Int. Cl. H05K 7/20

(52) U.S. Cl. 361/695

(57) ABSTRACT

A system and method for cooling a series of heat generating devices arrayed sequentially in the axis of flow for a cooling medium. An inlet manifold contains a stepped chamber whereby cool air is apportioned to several chambers, each chamber containing a heat generating device. An outlet manifold contains a similar stepped chamber whereby heated air is exhausted from the heat generating device. In an embodiment of a disk array, each chamber may hold one or more disk drives. Further, the manifold system may also serve as a mounting bracket for the disk drives.

### BACKGROUND OF THE INVENTION

a. Field of the Invention

The present invention pertains generally to forced air cooling systems and specifically to cooling systems containing several heat generating items in the primary axis of airflow.

b. Description of the Background

Space constraints of mechanical layouts of electronics systems have forced many devices in a small volume. One such problem exists in arrays of disk drives where some designs place many disk drives in a grid pattern inside an enclosure. In such a system, the airflow of the enclosure is such that the air must flow across several disk drives before exiting the enclosure. As the air flows through the enclosure, each device heats the air flowing past, causing the last device in line to be subject to air heated by the prior devices and suffer marginal cooling.

Each heat generating device must be cooled to a nominal temperature to maintain its performance standards and useful life. Some devices, such as disk drives, have known performance or longevity degradation at higher temperatures. A key to overall system performance is keeping each device properly cooled. Ideally, each device would be cooled to the same temperature, as the device at the highest temperature is generally more prone to failure.

In prior systems of disk based storage systems, many disk drives may be aligned along the front of the enclosure. When air is drawn through the enclosure from the front to the rear, each disk drive may be cooled without effecting the cooling of another disk drive.

In more advanced systems, several disk drives may be arrayed along the axis of the cooling stream. In such systems, the heat of an upstream disk drive may add heat to the airflow, subsequently raising the temperature of downstream disk drives. An additional constraint is the height of the enclosure is desired to be kept to a minimum to allow more enclosures to be placed in a given rack.

It would therefore be advantageous to provide a system and method whereby several heat generating devices may be sequentially aligned in an airflow axis while keeping the temperature of each device in the nominal operating range. It would be further advantageous if such a system were compact and simple to implement.

### SUMMARY OF THE INVENTION

The present invention overcomes the disadvantages and limitations of previous solutions by providing a system and method for cooling a series of heat generating devices arrayed sequentially in the axis of flow for a cooling medium. An inlet manifold contains a stepped chamber whereby cool air is apportioned to several chambers, each chamber containing a heat generating device. An outlet manifold contains a similar stepped chamber whereby heated air is exhausted from the heat generating device.

In an embodiment of a disk array, each chamber may hold one or more disk drives. Further, the manifold system may also serve as a mounting bracket for the disk drives.

An embodiment of the present invention may include a cooling system for system comprising a plurality of heat generating devices comprising: the plurality of heat generating devices substantially disposed along an array axis; an inlet having an inlet wall, an inlet axis of flow substantially parallel to the inlet wall, and an inlet edge; an outlet having an outlet wall, an outlet axis of flow substantially parallel to outlet wall, and an outlet edge; a first fin comprising a first edge that is disposed between the inlet wall and the inlet edge of the inlet, when the inlet is projected along the inlet axis, the first fin being further disposed between the plurality of heat generating devices; and a second fin comprising a first edge that is disposed between the inlet wall and the first edge of the first fin, when the inlet is projected along the inlet axis, the second fin being further disposed between the plurality of heat generating devices downstream from the first fin.

Another embodiment of the present invention may include a disk drive storage system comprising: an enclosure having a first face; a plurality of disk drives disposed along an array axis substantially perpendicular to the first face; an inlet having an inlet wall, an inlet axis of flow substantially parallel to the inlet wall, and an inlet edge; an outlet having an outlet wall, an outlet axis of flow substantially parallel to outlet wall, and an outlet edge; a first fin comprising a first edge that is disposed between the inlet wall and the inlet edge when the inlet is projected along the inlet axis, the first fin being further disposed between the plurality of disk drives; and a second fin comprising a first edge that is disposed between the inlet wall and the first edge of the first fin, when the inlet is projected along the inlet axis, the second fin being further disposed between the plurality of disk drives downstream from the first fin.

The advantages of the present invention are that multiple heat generating devices may be mounted in a compact package and cooled effectively. When the manifold system serves as a mounting bracket and heat sink for the heat generating devices, effective cooling is combined with lower overall system cost.

### BRIEF DESCRIPTION OF THE DRAWINGS

In the drawings,

FIG. 1 is a cross-sectional illustration of an embodiment of the present invention showing a cooling system for a disk drive storage system.

FIG. 2 is a cross-sectional illustration of an embodiment of the present invention showing a cooling system having a pressurized interior.

FIG. 3 is a semi-exploded perspective illustration of an embodiment of the present invention showing a disk storage system with a single piece manifold cooling system.

FIG. 4 is a semi-exploded perspective illustration of an embodiment of the present invention showing a disk storage system comprised of several manifolds.

FIG. 5 is a cross-sectional illustration of an embodiment of the present invention showing intake and exhaust axes that are not parallel with the line of heat generating devices.

### DETAILED DESCRIPTION OF THE INVENTION

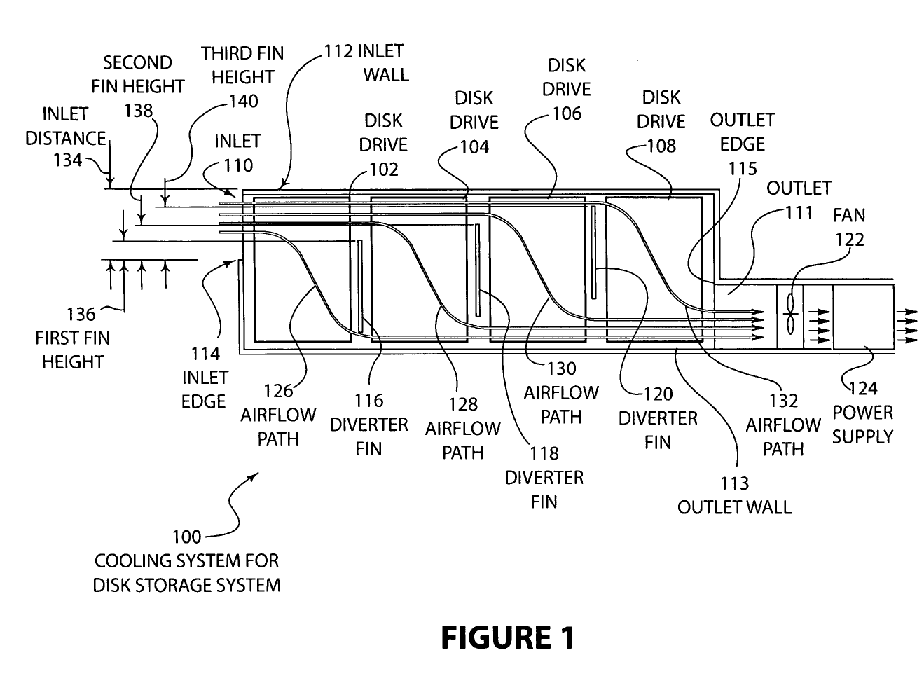

FIG. 1 illustrates an embodiment 100 of the present invention showing a cooling system for a disk drive storage system. The disk drives 102, 104, 106, and 108 are mounted downstream from an inlet 110. The inlet 110 has an inlet wall 112 and a inlet edge 114. Several diverter fins 116, 118, and 120 direct airflow around the disk drives and to the outlet 111. The outlet 111 has a outlet wall 113 and an outlet edge 115. Airflow is propelled by a fan 122, which exhausts into the power supply 124.

The airflow paths 126, 128, 130, and 132 show the airflow through the embodiment 100. As the air enters the inlet 110, a portion is diverted across disk drive 102 by airflow path 126. Similarly, airflow path 132 shows some air that passes a portion of disk drives 102, 104, and 106 before passing across disk drive 108. Airflow path 132 may be partially heated when passing over disk drives 102, 104, and 106, but because only a small portion of the three upstream disk drives are in its path, only a mild heating effect may take place.

The airflow paths 126, 128, 130, and 132 illustrate how an incoming airstream is broken into separate airstreams directed toward each heat generating device. After performing the primary cooling function of the specific device, the airflow paths are reunited and exhausted from the cavity. The primary benefit of splitting the incoming airstream is that cooling air may be directed at each specific heat generating device, with a minimum of pre-heating by other upstream heat generating devices.

In order to split the incoming airstream for each heat generating device, the diverter fins 116, 118, and 120 are positioned such that the upper lips or edges of the diverter fins are inside the projected area of the inlet. Further, the downstream fins are within the projected area of the inlet and any upstream fins.

For example, the inlet 110 is comprised of the inlet wall 112 and the inlet edge 114. The inlet axis is parallel to the inlet wall 112, and the inlet projects an area along the axis, as shown by the inlet distance 134. The first fin 116 is projected at a height 136 through the inlet 110. Similarly, the second fin 118 projects a height 138 and the third fin 120 projects a height 140. Each downstream fin is within the projected area of the inlet, masked by any upstream fin. In this manner, an incoming airstream may be split and diverted across a specific heat generating device. In the embodiment 100, the heat generating devices are the disk drives 102, 104, 106, and 108.

The inlet edge 114 in embodiment 100 is the highest projected edge of the lower portion of the inlet 110. In other embodiments, the inlet edge 114 may be formed from a wall that is straight or curved, depending on various design factors. For example, a curved duct may be used to convey cool air from one portion of an enclosure to the area near the heat generating devices. In such an embodiment, the uppermost portion of the lower portion of the ductwork would comprise the inlet edge 114, defining the inlet distance 134 with the inlet wall 112. The presence of a straight and discrete edge 114 does not limit the invention to the precise embodiment shown.

Further, the use of terminology as ‘upper’ and ‘lower’ in this application are merely for description purposes and are not meant to limit the invention. The terms ‘upper’ and ‘lower’ are used only to describe the relative position of a particular feature on the particular figure. For example, an inverted version of embodiment 100, where the inlet is nearest to the lower portion of the embodiment and the outlet near the upper portion is within the scope of the present invention.

In other embodiments, one or more heat generating devices may be present between the diverter fins. For example, in a disk drive storage system, two or more disk drives may be placed between a pair of diverter fins.

The fan 122 may be located downstream from the heat generating devices. In some embodiments, a power supply 124 may be located downstream from the heat generating devices. In embodiment 100, the fan 122 pulls air from the heat generating devices and pushes air into the power supply 124. In other embodiments, the fan 122 may be located downstream from the power supply 124. Various configurations may be contemplated by those skilled in the arts while keeping within the spirit and intent of the present invention.

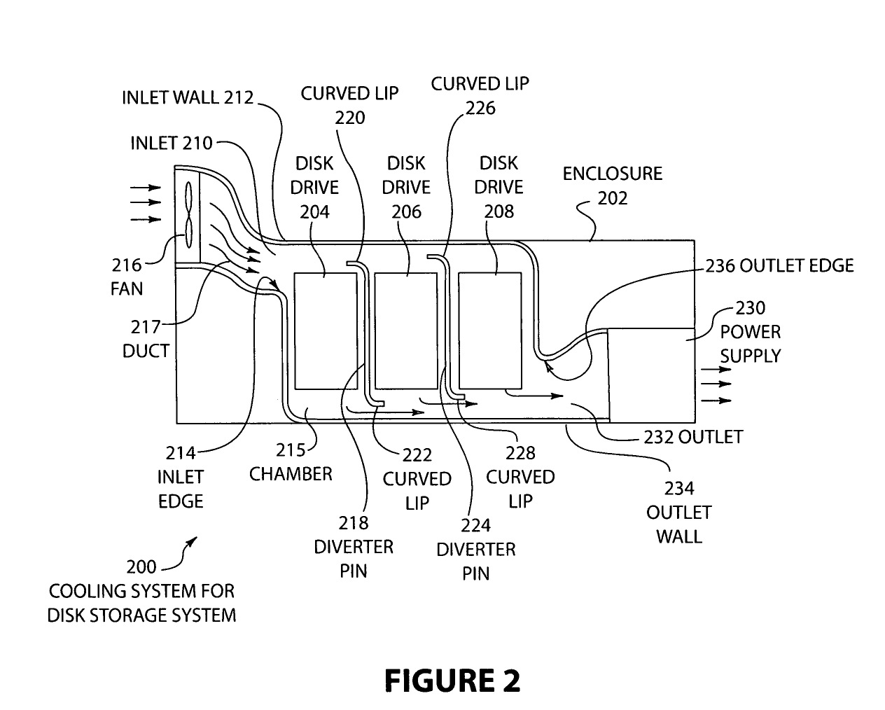

FIG. 2 illustrates an embodiment 200 of the present invention showing a cooling system having a pressurized interior. The enclosure 202 contains disk drives 204, 206, and 208.

The inlet 210 is comprised of an inlet wall 212 and the inlet edge 214. The inlet edge 214 is the point of least constriction nearest the opening of the chamber 215 containing the heat generating devices. In some embodiments, the ductwork transmitting the airflow into the chamber 215 may have narrow passages prior to entering the chamber 215. However, the inlet edge 214 is the narrowest point immediately prior to entering the chamber 215 that is opposite the inlet wall 212.

The fan 216 provides a positive pressure to the chamber 215. The exhaust of the fan 216 proceeds through a duct 217 to the chamber 215.

Between the various disk drives are diverter fins 218 and 224. The diverter fin 218 has curved lips 220 and 222 on the upstream and downstream ends, respectively. Similarly, diverter fin 224 has curved lips 226 and 228. The upstream lips 220 and 226 are designed to split the incoming airflow into separate streams to cool the various disk drives. Similarly, the downsteam lips 222 and 228 are designed to join the streams. Various shapes and sizes of diverter fins may be used by those skilled in the art while maintaining within the spirit and intention of the present invention. In some embodiments, the diverter fins may be identical in size and shape while in other embodiments the fins may be of various heights and shapes.

The airflow exits the enclosure 202 through the outlet 232, which is defined by the outlet wall 234 and the outlet edge 236. Similar to the inlet edge 214, the outlet edge 236 is the narrowest edge immediately downstream from the chamber 215. Subsequent ductwork does not effect the position of the outlet edge.

The power supply 230 is cooled by the air that evacuates the chamber 215. The power supply may be more tolerant of higher heat than the disk drives 204, 206, and 208 and may therefore withstand the preheated air and less cooling. In embodiments where a power supply is less tolerant than the other heat generating devices, the power supply may be placed upstream from the other heat generating devices.

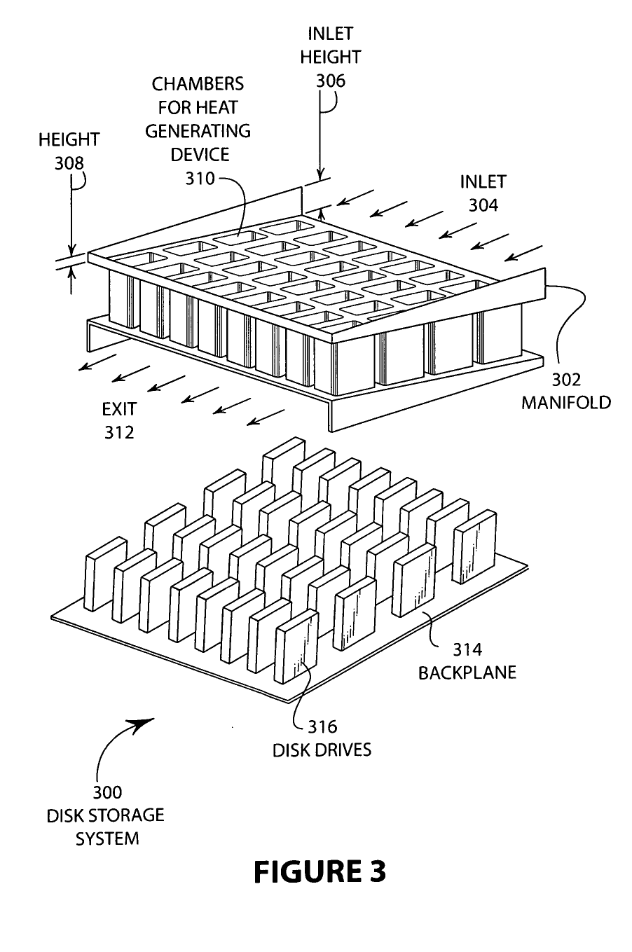

FIG. 3 illustrates an embodiment 300 of the present invention showing a disk storage system with a single piece manifold cooling system. The manifold 302 comprises an inlet 304 that has a sloped intake chamber, illustrated by the difference in the inlet height 306 and the height 308. Many separate chambers 310 are provided to direct airflow from the inlet 304 near the heat generating devices and out the exit 312.

The manifold 302 is placed over the backplane 314 to which are attached various disk drives 316. The disk drives 316 may be engaged directly onto the backplane 314 through a connector. The connector alone or additional mechanical supports may be used to mechanically attach the disk drives 316 to the backplane 314.

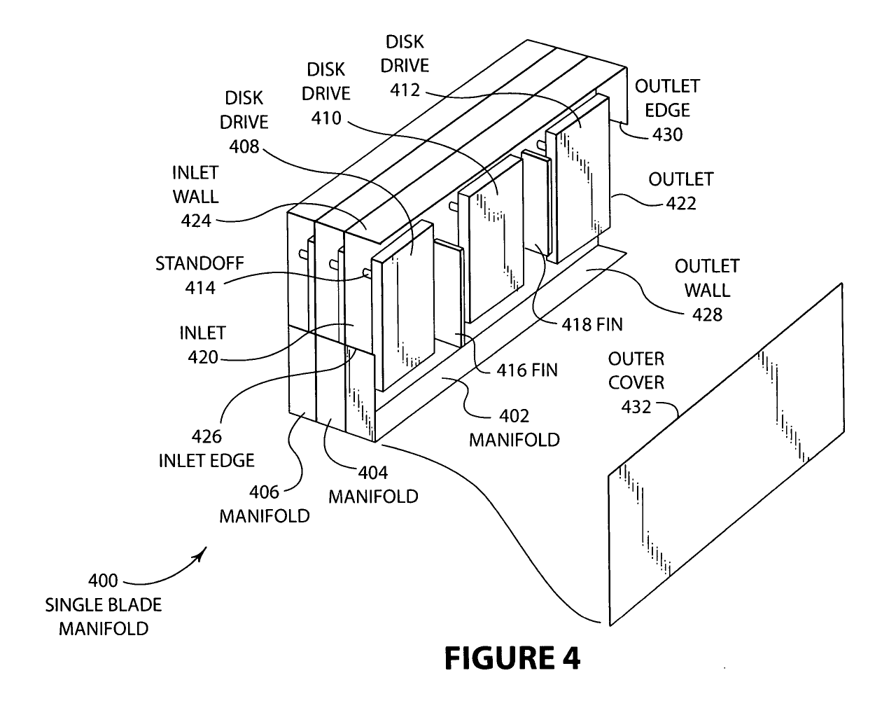

FIG. 4 illustrates an embodiment 400 of the present invention showing a disk storage system comprised of several manifolds. Each manifold 402, 404, and 406 contains multiple disk drives and serves both as a mechanical support as well as an airflow management device.

For example, manifold 402 contains disk drives 408, 410, and 412. Each disk drive may be mounted on standoffs 414. Fins 416 and 418 are positioned inside the manifold 402 to divert airflow from the inlet 420 and to the outlet 422. The inlet 420 has the inlet wall 424 and the inlet edge 426. Similarly, the outlet 422 has the outlet wall 428 and outlet edge 430.

The outer cover 432, shown removed from the assembly, seals manifold 402. The manifolds 404 and 406 may have a similar cover or may be positioned against each other to form a sealed chamber. In some embodiments, a gasket or other sealing material may be used to create an airtight seal around the chamber enclosing the disk drives, while in other embodiments only a loose fit without an airtight seal may be used.

The embodiment 400 uses several manifolds that, when stacked together, create a rectangular array of disk drives. Each disk drive is mounted to a manifold and may be connected to a backplane using a cabled connection. The manifold 402 may have the standoffs 414 molded or formed into the manifold 402. In some cases, the standoffs 414 may be separate mechanical parts. The manifolds 402, 404, and 406 may be held together by fasteners or other mechanisms including snap fit, external mechanisms, or any mechanical engagement. In some embodiments, a single manifold may be removable without having to disturb the neighboring manifolds. Those skilled in the arts may contemplate many different embodiments while keeping within the spirit and intention of the present invention.

In some embodiments, the manifold 402 may be a thermally conductive material. In such an embodiment, the disk drives 408, 410, and 412 may be mounted using thermally conductive adhesive or in some other manner so as to conduct as much heat from the disk drives to the manifold 402 as possible. In such an embodiment, the manifold 402 may act as a heat sink and dissipate heat into the airstream in addition to the convection of the disk drives themselves.

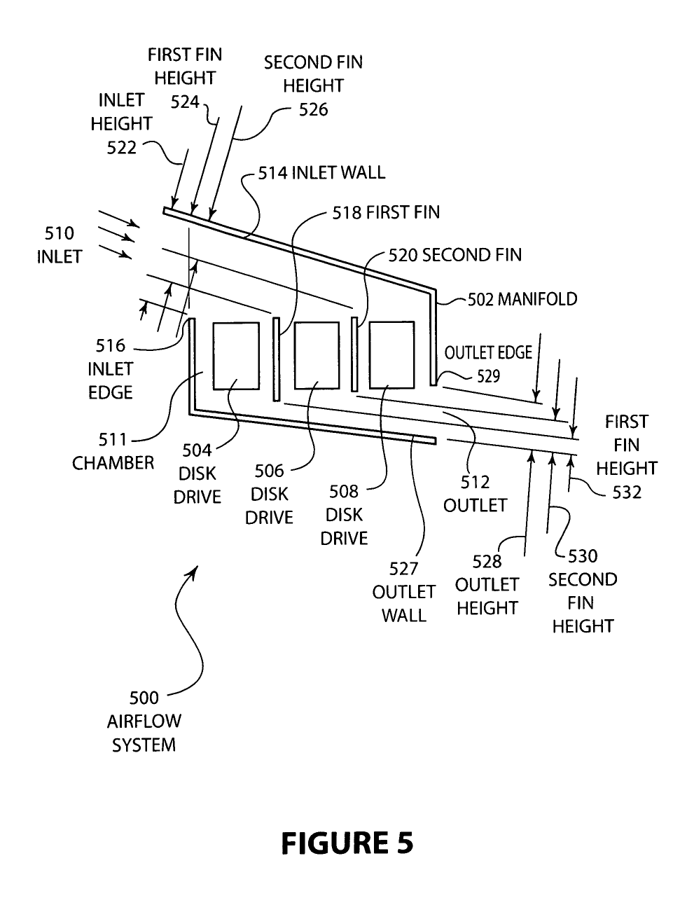

FIG. 5 illustrates an embodiment 500 of the present invention showing intake and exhaust axes that are not parallel with the line of heat generating devices. The manifold 502 contains disk drives 504, 506, and 508. Airflow is from the inlet 510, through the chamber 511, and out through the outlet 512.

The inlet 510 has an inlet wall 514 and an inlet edge 516. The inlet height 522 is shown projected along the inlet axis defined by the inlet wall 514. The first fin 518 has a projected height 524. Likewise, the second fin 520 has a projected height 526.

Similarly, the outlet 512 has an outlet wall 527 and an outlet edge 529. The outlet height 528 is shown projected along the outlet axis defined by the outlet wall 527. The second fin 520 has a projected height 530. Similarly, the first fin 518 has a projected height 532.

The embodiment 500 illustrates an embodiment where the inlet axis, an axis defined by the heat generating devices, and the outlet axis are not parallel. In both the inlet and outlet portions of the manifold 502, the fins 518 and 520 split the incoming and outgoing airflow based on the position of the edges as projected along the incoming and outgoing axes. Various geometries of the fins 518 and 520, inlet wall 514, and outlet wall 527 are possible while keeping within the spirit and intent of the present invention.

In the preceding embodiments, the cooling medium was referred to as air. In other embodiments, various cooling media may be used, including water, glycol, or other liquids, suspensions, or fluid mixtures. Additionally, various gasses may be used in place of air to perform the cooling function.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

1. A cooling system for system comprising a plurality of heat generating devices comprising:
said plurality of heat generating devices substantially disposed along an array axis;
an inlet having an inlet wall, an inlet axis of flow substantially parallel to said inlet wall, and an inlet edge;
an outlet having an outlet wall, an outlet axis of flow substantially parallel to said outlet wall, and an outlet edge;
a first fin comprising a first edge that is disposed between said inlet wall and said inlet edge, when said inlet is projected along said inlet axis, said first fin being further disposed between said plurality of heat generating devices; and
a second fin comprising a first edge that is disposed between said inlet wall and said first edge of said first fin, when said inlet is projected along said inlet axis, said second fin being further disposed between said plurality of heat generating devices downstream from said first fin.

2. The cooling system of claim 1 wherein said first fin further comprises a second edge disposed between said outlet edge and said outlet wall, when said outlet is projected along said outlet axis and said second fin further comprises a second edge disposed between said outlet edge and said second edge of said first fin, when said outlet is projected along said outlet axis.

3. The cooling system of claim 1 wherein said array axis is substantially parallel to said inlet axis.

4. The cooling system of claim 2 wherein said inlet axis is substantially parallel to said outlet axis.

5. The cooling system of claim 1 wherein said fin further comprises a body that is substantially straight and substantially perpendicular to said array axis.

6. The cooling system of claim 5 wherein said fin further comprises a curved lip proximate to said top edge.

7. The cooling system of claim 6 wherein said fin further comprises a curved lip proximate to said bottom edge.

8. The cooling system of claim 1 further comprising at least one fan mounted downstream from said outlet and adapted to evacuate said cooling system.

9. The cooling system of claim 1 further comprising at least one fan mounted upstream from said inlet and adapted to pressurize said cooling system.

10. A disk drive storage system comprising:
an enclosure;
a plurality of disk drives disposed along an array axis substantially perpendicular to said first face;
an inlet having an inlet wall, an inlet axis of flow substantially parallel to said inlet wall, and an inlet edge;
an outlet having an outlet wall, an outlet axis of flow substantially parallel to outlet wall, and an outlet edge;
a first fin comprising a first edge that is disposed between said inlet wall and said inlet edge when said inlet is projected along said inlet axis, said first fin being further disposed between said plurality of disk drives; and
a second fin comprising a first edge that is disposed between said inlet wall and said first edge of said first fin when said inlet is projected along said inlet axis, said second fin being further disposed between said plurality of disk drives downstream from said first fin.

11. The disk drive storage system of claim 10 wherein said first fin further comprises a second edge disposed between said outlet edge and said outlet wall, when said outlet is projected along said outlet axis, and said second fin further comprises a second edge disposed between said outlet edge and said second edge of said first fin, when said outlet is projected along said outlet axis.

12. The disk drive storage system of claim 10 wherein said array axis is substantially parallel to said inlet axis.

13. The disk drive storage system of claim 111 wherein said inlet axis is substantially parallel to said outlet axis.

14. The disk drive storage system of claim 10 wherein said disk drives are connected to said backplane by direct connections.

15. The disk drive storage system of claim 10 wherein said disk drives are connected to said backplane by cable connections.

16. The disk drive storage system of claim 10 wherein said fin further comprises a body that is substantially straight and substantially perpendicular to said array axis.

17. The disk drive storage system of claim 10 further comprising at least one fan mounted downstream from said outlet and adapted to evacuate said cooling system.

18. The disk drive storage system of claim 10 further comprising at least one fan mounted upstream from said inlet and adapted to pressurize said cooling system.

19. The disk drive storage system of claim 10 further comprising at least one power supply mounted downstream of said outlet and adapted to receive airflow from said outlet.

20. The disk drive storage system of claim 19 further comprising at least one fan mounted downstream of said outlet and upstream from said at least one power supply.

21. The disk drive storage system of claim 10 further comprising a manifold to which said plurality of disk drives are mounted.

22. The disk drive storage system of claim 22 further comprising a plurality of said manifolds disposed substantially parallel to each other.
